(19) United States
(12) Patent Application Publication
(10) Pub. No.: US 2026/0242924 A1
(43) Pub. Date: Aug. 20, 2026

(54) RESIDUAL LIQUID METAL TREATMENT DURING LED FABRICATION

(71) Applicant: Applied Materials, Inc., Santa Clara, CA (US)

(72) Inventors: Peiwen LIU, Fremont, CA (US); Uma SRIDHAR, Sunnyvale, CA (US); Kai DING, Cupertino, CA (US); Mingwei ZHU, San Jose, CA (US); Sivapackia GANAPATHIAPPAN, Los Altos, CA (US); Hou T. NG, Campbell, CA (US); Nag B. PATIBANDLA, Santa Clara, CA (US)

(21) Appl. No.: 19/159,508

(22) PCT Filed: Mar. 13, 2024
(86) PCT No.: PCT/US2024/019739

§ 371 Date: Aug. 25, 2025

Related U.S. Application Data
(60) Provisional application No. 63/490,415, filed on Mar. 15, 2023.

(51) Int. Cl. C23C 8/42; B23K 26/36; C23C 8/80; H10H 29/01; H10H 29/24

(52) U.S. Cl. CPC C23C 8/42; B23K 26/36; C23C 8/80; H10H 29/01; H10H 29/24

(57) ABSTRACT

The present disclosure generally includes a method for forming a light emitting diode (LED) device, that includes using laser irradiation to remove a carrier substrate from the LED device, oxidizing a residual liquid metal layer formed by the laser irradiation by soaking the LED device in heated de-ionized water, rinsing the de-ionized water off the LED device, and drying the LED device using a drying process.

### BACKGROUND

### Field

Embodiments of the present disclosure generally relate to methods for forming light-emitting diode (LED) devices. More particularly, embodiments of the present disclosure relate to removing a residual liquid metal layer formed during fabrication of an LED device.

### Description of the Related Art

Light-emitting diode (LED) panels use LED arrays with individual LEDs that each control individual pixel elements. LED panels may be used for computer displays, televisions, smart phone screens, and the like. Typically, the individual LEDs are gallium nitride (GaN) based and are formed on a carrier substrate. After fabricating the LEDs on the carrier substrate, the LEDs may be attached (i.e., transferred) to a backplane or an interposer of the LED panel and the carrier substrate is removed. However, the removal of the carrier substrate may damage the LED materials and/or the backplane/interposer, or leave a residual liquid metal layer in place of the carrier substrate. The reflectivity of the residual liquid metal layer may reduce the luminous efficiency of the LEDs. Accordingly, what is needed in the art is a method to remove the carrier substrate with reduced damage and/or with reduced hinderance of the performance of the LED panel.

### SUMMARY

The present disclosure generally includes a method for forming a light emitting diode (LED) device, that includes using laser irradiation to remove a carrier substrate from the LED device, oxidizing a residual liquid metal layer formed by the laser irradiation by soaking the LED device in heated de-ionized water, rinsing the de-ionized water off the LED device, and drying the LED device using a drying process.

Embodiments of the present disclosure may further provide a method for forming a light emitting diode (LED) device including using laser irradiation to remove a carrier substrate from the LED device, the carrier substrate having gallium nitride (GaN) LEDs formed on a carrier surface of the carrier substrate, oxidizing a Ga residual layer formed by the laser irradiation by soaking the LED device in heated de-ionized water, rinsing the de-ionized water off the LED device, and drying the LED device using a drying process.

Embodiments of the present disclosure may further provide Embodiments of the present disclosure may further provide a device including a backplane having backplane electrodes, and a plurality of light emitting diodes (LEDs) coupled to the backplane, the plurality of LEDs including a transparent layer formed on a first side of an epilayer, and LED electrodes formed on a second side of the epilayer that are coupled to the backplane electrodes.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, and may admit to other equally effective embodiments.

FIG. 1 is a flow diagram of a method for coupling an LED to a backplane of a display panel using a direct die transfer process, according to one or more embodiments.

FIGS. 2A-2H are schematic diagrams illustrating treatment of a residual liquid metal layer formed on an LED device fabricated using a single die transfer process, according to one or more embodiments.

FIG. 3 is a flow diagram of a method for treating a residual liquid metal layer formed on an LED device that is fabricated using a double die transfer process, according to one or more embodiments.

FIGS. 4A-4H are schematic diagrams illustrating treatment of a residual liquid metal layer formed on an LED device fabricated using a double die transfer process, according to one or more embodiments.

FIG. 5 is a cross-sectional view of a pixel 500, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to forming light emitting diode (LED) devices. More particularly, embodiments of the present disclosure relate to treating a residual liquid metal layer formed on an LED device caused by removing a carrier substrate using laser irradiation to improve the performance of the LED device.

Typically, LEDs are fabricated on a carrier substrate. After LEDs are formed, the LEDs are transferred (attached) to a die. The LEDs may be transferred in a direct die transfer to a backplane or may be transferred to an interposer in a double die transfer process. After the LEDs are attached to a die, the carrier substrate is removed.

The carrier substrate may be removed by laser irradiance. However, the laser irradiance removal may leave behind a residual liquid metal layer. The composition of the residual liquid metal layer is based on the composition of the LEDs. For example, gallium nitride (GaN) based LEDs may leave behind residual gallium (Ga). Problematically, the reflectivity of the residual liquid metal layer reduces the luminous efficiency of the LEDs. Embodiments disclosed herein relate to treating the residual liquid metal layer to increase its transparency and improve the performance of the LEDs.

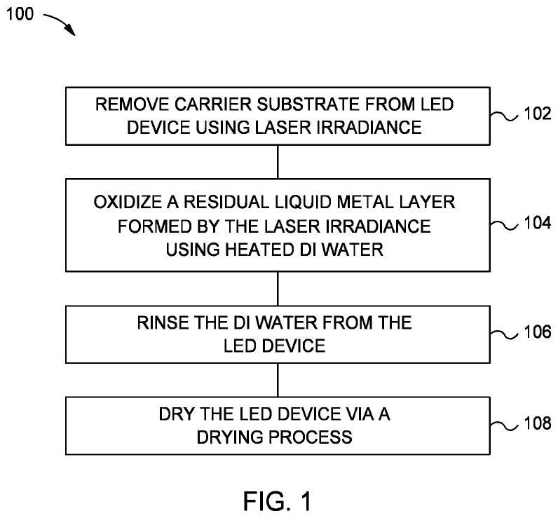

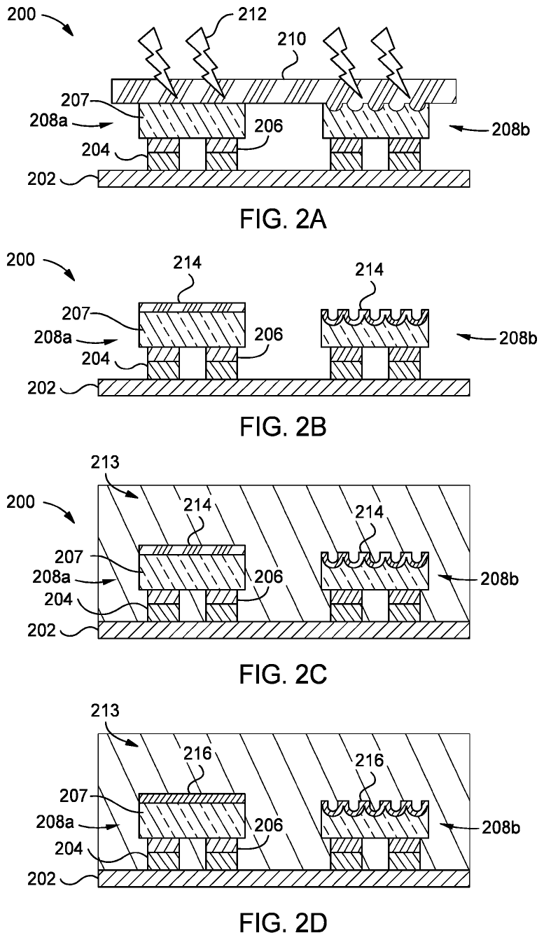

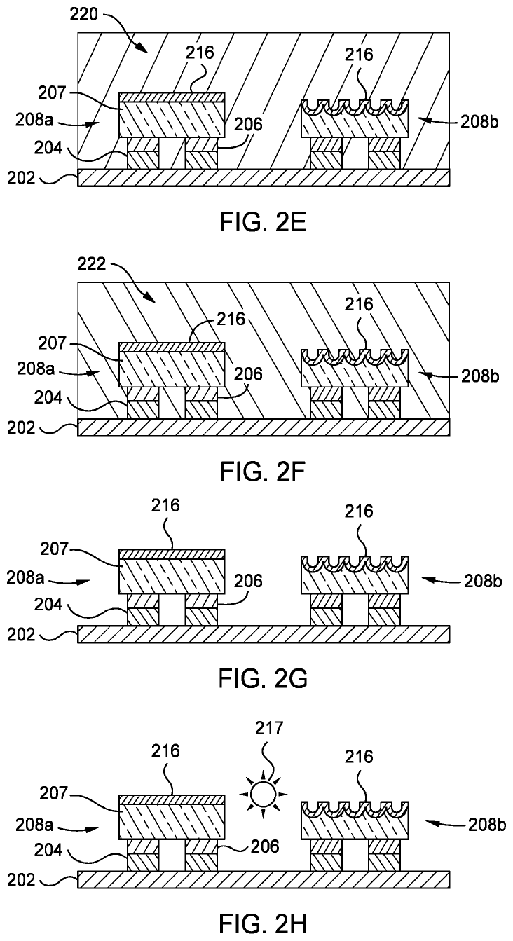

FIG. 1 is a flow diagram of a method 100 for treating a residual liquid metal layer formed on an LED device that is fabricated using a single die transfer process, according to one or more embodiments. FIGS. 2A-2H are schematic diagrams for treating a residual liquid metal layer formed on an LED device 200 that is fabricated using a single die transfer process, according to one or more embodiments. To facilitate understanding, FIGS. 1 and 2 will be explained in conjunction.

At operation 102, as illustrated in FIG. 2A, carrier substrate 210 is removed from the LED device 200 using laser irradiance 212 (e.g., laser lift-off).

The LED device 200 includes a carrier substrate 210 that has a plurality of LEDs formed or grown overlying a carrier surface of the carrier substrate 210. The carrier substrate 210 may have a diameter of any suitable size, such as 50 mm to 100 mm, for example. The carrier substrate 210 may comprise at least one of sapphire, silicon carbide (SIC), gallium nitride (GaN), silicon, quartz, gallium arsenide (GaAs), aluminum nitride (AlN), and glass. In one example, the plurality of LEDs includes LED 208a and LED 208b. Although the carrier substrate 210 includes two LEDs as shown, it is to be understood that the carrier substrate 210 may have hundreds, thousands, millions, or more LEDs. Furthermore, each of the LEDs formed on the carrier substrate 210 may be regular LEDs, PSS LEDs, or combinations thereof. For example, as illustrated in FIG. 2A, the LED 208b may be a PSS LED. Each of the LEDs 208A-208B may be macro, mini, micro LEDs, or any other sized LED. The LEDs 208A-208B may be fabricated by growing a plurality of layers onto the carrier surface of the carrier substrate 210. The LEDs 208a-208b may each include an epilayer 208 formed on the carrier substrate 210 that acts as an electrical component that generates light. The epilayer 207 may include a first surface 207a that contacts the carrier surface of the carrier substrate 210, and a second surface 207b opposite the first surface 207a. The epilayer 207 overlying the carrier substrate 210 may include any number of materials and/or layers. In some embodiments, the epilayer 207 may be manufactured using layer(s) of group III-V films. In one embodiment, the epilayer 207 may be gallium nitride (GaN) based. For example, the epilayer 207 may be a gallium- and nitrogen containing LED structure that is epitaxially formed on the carrier substrate 210. Although the epilayer 207 is shown as a single layer in these figures, it should be understood that the epilayer 207 may in fact be formed using a plurality of continuous layers that are built up on the carrier substrate 210. For example, the epilayer 207 may include an n-doped GaN layer and a p-doped GaN layer. Furthermore, the epilayer 207 may include a multiple-quantum-well (MQW) region between the n-doped GaN layer and the p-doped GaN layer

One or more electrodes may be disposed onto the epilayer 207. As an example, a plurality of LED electrodes 206 may be formed on the second surface 207b of the epilayer 207. The LED electrodes 206 may comprise a first material including, but are not limited to, gold (Au), indium (In), indium tin oxide (ITO), or the like.

A backplane 202 may include backplane electrodes 204 coupled thereto. The backplane electrodes 204 may be configured to couple with a corresponding LED electrode 206 to form electrical connections between the LEDs 208a-208b and the backplane 202. The backplane electrodes may comprise a second material including, but not limited to, gold (Au), indium (In), indium tin oxide (ITO), or the like. In certain embodiments, the first material and the second material are different. For example, the circuity of the backplane 202 can include a TFT active matrix array with a thin-film transistor and a storage capacitor (not illustrated) for each of the LEDS 208a-208b, column address and row address lines, column and row drivers, to drive the LEDs. Alternatively, the LEDS 208a-208b can be driven by a passive matrix in the backplane circuitry. The backplane 202 can be fabricated using conventional complementary metal-oxide silicon (CMOS) process. Each of the backplane electrodes 204 are configured to couple to a corresponding LED structure. The LED device 200 may be mounted to the backplane by mating the LED electrodes 206 to the backplane electrodes 204. Then, using laser irradiance 212 (operation 102), the carrier substrate 210 is vaporized and removed to expose the first surface 207a of the epilayer 207 over the backplane 202. Although only two LEDs 208A-208B are included in the LED device 200, it should be understood that this is for example purposes only, and more or less than two LEDs may be included in the LED device 200. Furthermore, although the LEDs 208A-208B each have LED electrodes 206 formed on the second surface 207b of the epilayer 207 one of the LEDs may have LED electrodes 206 that are formed between the epilayer 207 and the carrier surface of the carrier substrate 210. For example, the LED 208b may include LED electrodes disposed on the first surface 207a of the epilayer 207, while the LED 208a includes LED electrodes 206 that may be formed on the second surface 207b of the epilayer 207 (or vice versa).

However, as shown in FIG. 2B, even though removing the carrier substrate 210 using laser irradiance 212 prevents damage to the LED device 200, a residual liquid metal layer 214 is left behind on the first surface 207a of the epilayer 207. The residual liquid metal layer 214 is based on the composition of the epilayer 207. For example, if the LEDs 208a-208b (the epilayer 207) are GaN based, the residual liquid metal layer 214 may comprise Ga. Although the residual liquid metal layer 214 is described as comprising Ga, this is for example purposes only, and the residual liquid metal layer 214 may comprise other materials.

The residual liquid metal layer 214 may have a thickness ranging from tens to hundreds of nanometers and reduce the luminous efficiency of the LED device 200 due to the reflective nature of Ga (or any other liquid metal). As described above, conventionally, the residual liquid metal layer 214 may be removed using HCL. However HCL is a harmful acid which may attack and cause damage to the LEDs 208A-208B, the backplane 202, the LED electrodes 206, the backplane electrodes 204, and combinations thereof. Embodiments herein describe a method for treating the residual liquid metal layer 214 using de-ionized (DI) water in lieu of HCL to protect the integrity of the LED device 200.

At operation 104, as illustrated in FIGS. 2C-2D, the residual liquid metal layer 214 is oxidized. In one embodiment, the residual liquid metal layer 214 is oxidized by soaking the LED device 200 in heated de-ionized (DI) water 213. The heated DI water 213 may be heated to a temperature between 60 and 100° C. and the LED device 200 may be soaked for a duration between 10 minutes and 3 hours. For example the LED device 200 is soaked in heated DI water 213 having a temperature of 75° C. for one hour. In one embodiment, as shown in FIG. 2D, the residual liquid metal layer 214 interacts with the heated DI water 213. The interaction between the heated DI water 213 and the residual liquid metal layer 214 releases hydrogen, transforming the residual liquid metal layer 214 into a transparent layer 216. In one or more examples, the transparent layer 216 is transparent to light having wavelengths within the visible light spectrum. In another example, the transparent layer 216 is transparent to light having wavelengths in the infrared (IR) wavelength spectrum. Due to the reaction between the residual liquid metal layer 214 and the heated DI water 213, the residual liquid metal layer 214 may transform into gallium oxide hydroxide (GaOH), gallium hydroxide (GaH), or combinations thereof. Stated differently, the transparent layer 216 may comprise GaOH, GaH, or combinations thereof.

At operation 106, as illustrated in FIGS. 2E-2F the heated DI water 213 is rinsed off the LED device 200. Rinsing the heated DI water 213 off the LED device 200 may include rising/soaking the LED device 200 using a first soaking process followed by a second soaking process. The first soaking process may include rinsing/soaking the LED device 200 in a first solvent 220 (FIG. 2E) for a first duration of time. The second soaking process may include rising/soaking the LED device 200 in a second solvent 222 (FIG. 2F) for a second duration of time. The first solvent 220 may be, but is not limited to, acetone. The second solvent 222 may be, but is not limited to, isopropyl alcohol (IPA). The first duration of time may be between 5 and 60 seconds. The second duration of time may be between 5 and 60 seconds. Advantageously, rinsing the heated DI water 213 off the LED device 200 using the first soaking process followed by the second soaking process provides a more complete clean of the LED device 200 and removes organic residue that is left on the LED device 200.

However in some examples, the heated DI water 213 is rinsed off the LED device 200 using only the first soaking process. In another example, the heated DI water 213 is rinsed off the LED device 200 using only the second soaking process. Although only one soaking process may be used, the first soaking process is preferred because acetone provides a more complete clean than IPA.

At operation 108, as illustrated in FIGS. 2G-2H, the LED device 200 undergoes a drying process. The drying process may include a first drying process followed by a second drying process. The first drying process may include air drying the LED device 200 (FIG. 2G) for a third duration of time. The second drying process may include heating or baking the LED device 200 at a temperature using a heat source 217 (FIG. 2H) for a fourth duration of time. The heat source 217 may include, but is not limited to, a resistive heat source such as a hot plate, or an oven. For example, the second drying process may include drying the LED device 200 by placing the LED device 200 on (i.e., in direct contact with) a resistive heat source or baking the LED device 200 in an oven. The third duration of time may range between 1 and 5 minutes. The temperature may range between 60 and 120° C., and the fourth duration of time may range between 30 seconds and 20 min. For example, the LED device 200 may be heated at a temperature of 80° C. for 3 minutes.

Advantageously, using the first drying process followed by the second drying process assists in drying both the surface and removing moisture in the interior of the LED device 200. In some embodiments, the LED device 200 may only undergo the first drying process. In another example, the LED device 200 may only undergo the second drying process. In some examples, if only one drying process is to be used, it is preferable to use the second drying process because the second drying process is more efficient at completely removing moisture from the LED device 200. However, as noted above the LED device 200 can be dried solely using the first drying process. If only the second drying process is used, heating the LED device 200 with a resistive heat source is preferred over baking the LED device 200. Heating the LED device 200 on a resistive heat source dries the entire LED device 200 more efficiently. However, in some embodiments, the LED device 200 can be dried solely by baking the LED device 200 in an oven (the second drying process).

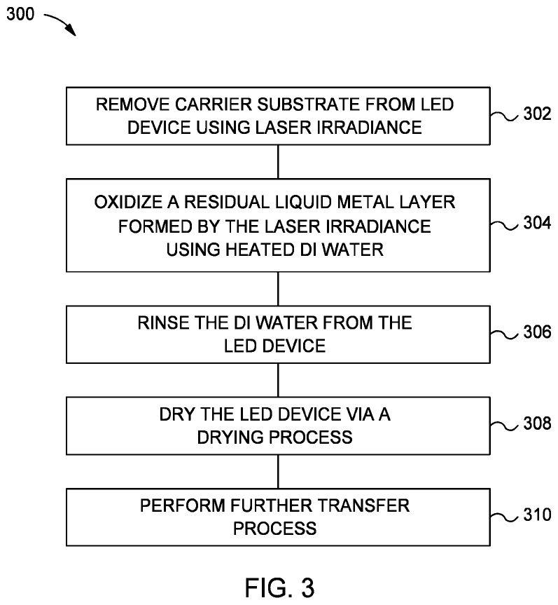

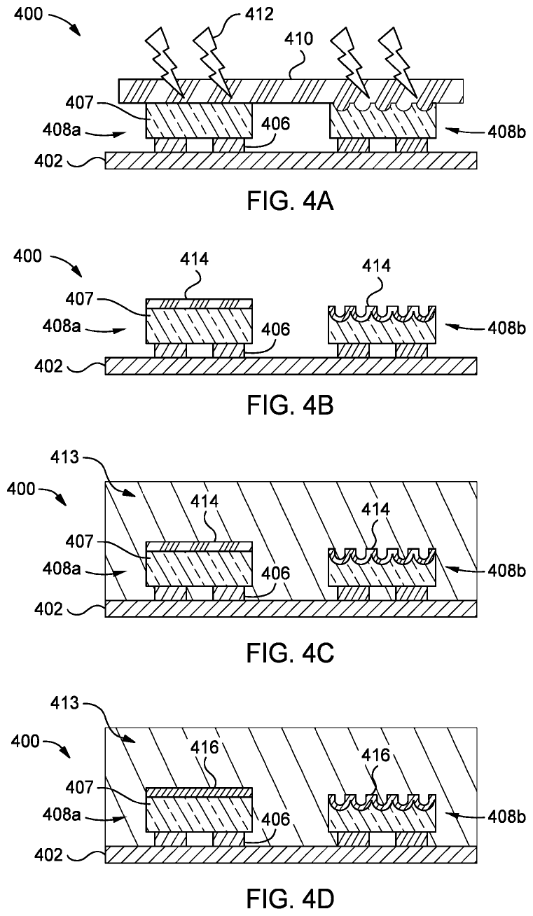

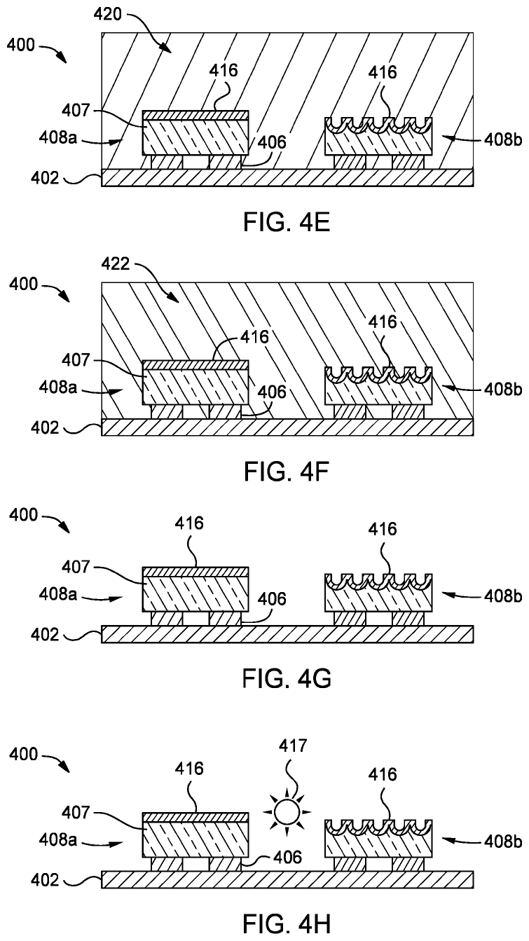

FIG. 3 is a flow diagram of a method 300 for treating a residual liquid metal layer formed on an LED device that is fabricated using a double die transfer process, according to one or more embodiments. FIGS. 4A-4H are schematic diagrams for treating a residual liquid metal layer formed on an LED device 400 that is fabricated using a double die transfer process, according to one or more embodiments.

At operation 302, as illustrated in FIG. 4A, the carrier substrate 410 is removed from the LED device 400 using laser irradiance.

The LED device 400 includes carrier substrate 410, having a plurality of LEDs being formed or grown overlying a carrier surface of the carrier substrate 410. The carrier substrate 410 may have a diameter of any suitable size, such as 50 mm to 100 mm, for example. The carrier substrate 410 may comprise of at least one of sapphire, silicon carbide (SiC), gallium nitride (GaN), silicon, quartz, gallium arsenide (GaAs), aluminum nitride (AlN), and glass. In one example, the plurality of LEDs includes a first LED 408A and a second LED 408B. Although the carrier substrate 410 includes two LEDs as shown, it is to be understood that the carrier substrate 410 may have hundreds, thousands, millions, or more LEDs. Furthermore, each of the LEDs formed on the carrier substrate 410 may be regular LEDs, PSS LEDs, or combinations thereof. For example, as illustrated in FIG. 4A, the second LED 408b may be a PSS LED. Each of the LEDs 408A-408B may be macro, mini, micro LEDs, or any other sized LED. The LEDs 408A-408B may be fabricated by growing a plurality of layers onto the carrier surface of the carrier substrate 410. The LEDs 408a-408b may each include an epilayer 407 formed on the carrier substrate 410 that acts as an electrical component that generates light. The epilayer 407 overlying the carrier substrate 410 may include any number of materials and/or layers. The epilayer 407 may include a first surface 407a that contacts the carrier surface of the carrier substrate 410, and a second surface 407b opposite the first surface 407a. The epilayer 407 overlying the carrier substrate 410 may include any number of materials and/or layers. In some embodiments, the epilayer 407 may be manufactured using layer(s) of group III-V films. In one embodiment, the epilayer 407 may be gallium nitride (GaN) based. For example, the epilayer 407 may be a gallium-and-nitrogen containing LED structure that is epitaxially formed on the carrier substrate 410. Although the epilayer 407 is shown as a single layer in these figures, it should be understood that the epilayer 407 may in fact be formed using a plurality of continuous layers that are built up on the carrier substrate 210. For example, the epilayer 407 may include an n-doped GaN layer and a p-doped GaN layer. Furthermore, the epilayer 407 may include a multiple-quantum-well (MQW) region between the n-doped GaN layer and the p-doped GaN layer.

One or more electrodes may be disposed onto the epilayer 407. As an example, a plurality of LED electrodes 406 may be formed on the second surface 407b of the epilayer 407 that is opposite the carrier surface of the carrier substrate 410. The LED electrodes 406 may comprise, but are not limited to, gold (Au), indium (In), indium tin oxide (ITO), or the like. In one or more embodiments, the LED electrodes 406 may be transferred (i.e., attached) to an interposer 402. The interposer may comprise, but is not limited to, an adhesive polymer. Then, using laser irradiance 412, the carrier substrate 410 is vaporized and removed to expose the first surface 407a of the epilayer 407 over the interposer 402 (operation 102). Although only two LEDs 408A-408B are included in the LED device 400, it should be understood that this is for example purposes only, and more or less than two LEDs may be included in the LED device 400.

However, as illustrated in FIG. 4B, even though removing the carrier substrate 410 using laser irradiance 412 prevents damage to the LED device 400, a residual liquid metal layer 414 is left behind based on the composition of the epilayer 407. For example if the LEDs 408A-408B (the epilayer 407) are GaN based, the residual liquid metal layer 414 may comprise Ga. Although the residual liquid metal layer 414 is described as a Ga residual layer, this is for example purposes only, and the residual liquid metal layer 414 may comprise different materials.

At operation 304, as illustrated in FIGS. 4C-4D, the residual liquid metal layer 414 is oxidized. In one embodiment, the residual liquid metal layer 414 is oxidized by soaking the LED device 400 in heated de-ionized (DI) water 413. The heated DI water 413 may be heated to a temperature between 60 and 120° C. and the LED device 400 may be soaked for a duration between 10 minutes and 3 hours. For example, the LED device 400 may be soaked in heated DI water 413 for 1 hour at 75° C. In one embodiment, as shown in FIG. 4D, the residual liquid metal layer 414 interacts with the heated DI water 413. The interaction between the heated DI water 413 and the residual liquid metal layer 414 releases hydrogen, transforming the residual liquid metal layer 414 into a transparent layer 416. In one or more examples, the transparent layer 416 is transparent to light having wavelengths within the visible light spectrum. In another example, the transparent layer 416 is transparent to light having wavelengths in the infrared (IR) wavelength spectrum. Due to the reaction between the residual liquid metal layer 414 and the heated DI water, the residual liquid metal layer 414 may transform into gallium oxide hydroxide (GaOH), gallium hydroxide (GaH) or combinations thereof. Stated differently, the transparent layer 416 may comprise GaOH, GaH, or combinations thereof.

At operation 306, as illustrated in FIGS. 4E-4F, the heated DI water 413 is rinsed off the LED device 400. Rinsing the heated DI water 413 off the LED device 400 may include rising/soaking the LED device 400 using a first soaking process followed by a second soaking process. The first soaking process includes rinsing/soaking the LED device 400 in a first solvent 420 for a first duration of time. The second soaking process includes rinsing/soaking the LED device 400 in a second solvent 422 for a second duration of time. The first solvent 420 may be, but is not limited to, acetone. The second solvent 422 may be, but is not limited to, isopropyl alcohol (IPA). The first duration of time may be between 5 and 60 seconds. The second duration of time may be between 5 and 60 seconds. Advantageously, rinsing the heated DI water 413 off the LED device 400 using the first soaking process followed by the second soaking process facilitates more complete cleaning of the LED device 400 and removes organic residue that is left on the LED device 200.

However in some examples, the heated DI water 413 is rinsed off the LED device 400 using only the first soaking process. In another example, the heated DI water 413 is rinsed off the LED device 400 using only the second soaking process. Although only one soaking process may be used, the first soaking process is preferred because acetone provides a more complete clean than IPA.

At operation 308, as illustrated in FIGS. 4G-4H, the LED device 400 undergoes a drying process. The drying process may include a first drying process followed by a second drying process. The first drying process may include air drying the LED device 400 (FIG. 4G) for a third duration of time. The second drying process may include heating or baking the LED device 400 at a temperature using a heat source 417 (FIG. 4H) for a fourth duration of time. The heat source 417 may include, but is not limited to, a resistive heat source such as hot plate, or an oven. For example, the second drying process may include drying the LED device 400 by heating the LED device 400 by placing the LED device 400 on (i.e., in direct contact with) a resistive heat source or baking the LED device 400 in an oven. The third duration of time may range between 1 and 5 minutes. The temperature may range between 60 and 120° C., and the fourth duration of time may range between 30 seconds and 20 min.

Advantageously, using the first drying process followed by the second drying process assists in drying both the surface and removing moisture in the interior of the LED device 400. In some embodiments, the LED device 400 may only undergo the first drying process. In another example, the LED device 400 may only undergo the second drying process. In some examples, if only one drying process is to be used, it is preferable to use the second drying process because the second drying process is more efficient at completely removing moisture from the LED device 400. However, as noted above the LED device 400 can be dried solely using the first drying process. If only the second drying process is used, heating the LED device 400 with a resistive heat source is preferred over baking the LED device 400. Heating the LED device 400 on a resistive heat source would dry the entire LED device 400 more efficiently. However, in some embodiments, the LED device 400 can be dried solely by baking the LED device 400 in an oven (the second drying process).

For example, the LED device 400 may be heated at a temperature of 80° C. for 3 minutes. In one example, the LED device 400 may only undergo the first drying process. In another example, the LED device 400 may only undergo the second drying process.

At operation 310, the LED device 400 undergoes an additional transfer process. For example, the interposer 402 is transferred to a backplane.

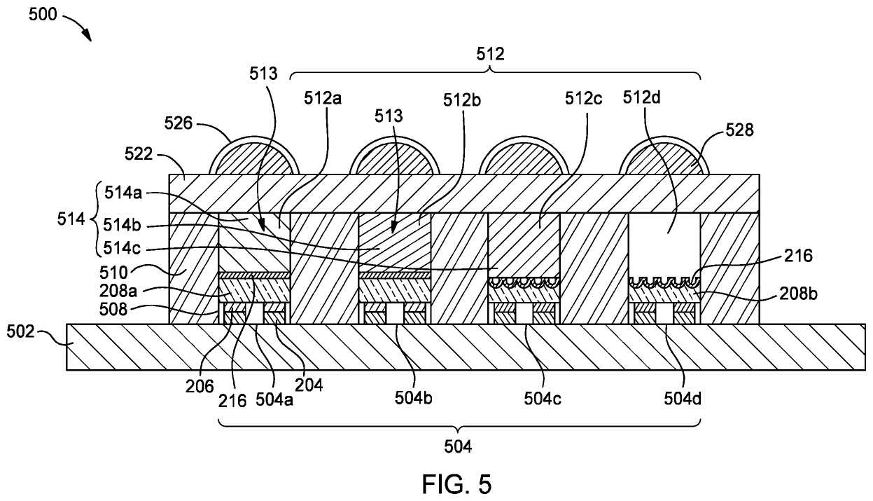

FIG. 5 is a cross-sectional view of a pixel 500, according to one or more embodiments. The pixel 500 includes at least four LEDs 504 disposed on a backplane 502. For example the pixel 500 includes two LEDs 208a and two LEDs 208b. The pixel 500 may include the same or different types of LEDs. The LEDs are connected to the backplane 502 via backplane electrodes 204 and LED electrodes 206.

As illustrated in FIG. 5 and shown above, a transparent layer 216 is formed over the epilayer 207. As explained above, after removing the carrier substrate 210 a residual liquid metal layer 214 is left behind. Conventionally, the residual liquid metal layer 214 may be removed using HCL. However HCL is a harmful acid which may attack and cause damage to the LEDs 504, the backplane 502, the LED electrodes 206, the backplane electrodes 204, and combinations thereof. Therefore, instead of removing the residual liquid metal layer 214, the residual liquid metal layer 214 is treated using heated DI water 213 (i.e., method 100) to form a transparent layer 216 that protects the integrity of the LEDs. Stated otherwise, each of the LEDs 504 include a transparent layer 216 formed over the epilayer 207.

SI structures 510 are disposed over, and in some embodiments on, the backplane 502. The adjacent SI structures 510 define a respective well 513 of at least three sub-pixels 512. Each LED is disposed in each well 513 between the adjacent SI structures 510. Each well 513 has a width from about 0.5 um to about 40 um, such as about 2 um to about 30 um. The SI structures 510 have a width from about 0.1 um to about 15 um such as 1 um to 10 um. The SI structures 510 may include organic material, such as epoxy-based photoresist.

The sub-pixels 512 include a first sub-pixel 512a with a red color conversion material 514a disposed in the well 513 of the first sub-pixel 512a, a second sub-pixel 512b with a blue color conversion material 514b disposed in the well 513 of the second sub-pixel 512b, and a third sub-pixel 512c with a green color conversion material 514c disposed in the well 513 of the third sub-pixel 512c. When an LED 504a of the first sub-pixel 512a is turned on the red color conversion material 514a will convert the light emitted from micro-LED 504a into red light. When a LED 504b of the second sub-pixel 512b is turned on the blue color conversion material 514b will convert the light emitted from LED 504b into blue light. When a LED 504c of the third sub-pixel 512c is turned on the green color conversion material 514c will convert the light emitted from micro-LED 504c into green light. In one embodiment, the pixel 500 includes a fourth sub-pixel 512d. As shown in FIG. 5, the fourth sub-pixel 512d does not include a color conversion material, i.e., color-conversion-layer-free. In some embodiments, the fourth sub-pixel 512d may be later filled with a color conversion material 514 (e.g., a red, green, blue, violet, etc. color conversion material). In another embodiment, the fourth sub-pixel 112d includes a sacrificial material (not shown). In other embodiments, the at least three sub-pixels 512 include the same color conversion material. The fourth sub-pixel 512d may be later filled with a color conversion material 514.

In some embodiments, the color conversion material 514 may include quantum dots (QDs). The quantum dots may be sized to produce wavelengths corresponding to different colors. In one embodiment, the red color conversion material 514a may include quantum dots approximately 6 nm in size. The blue color conversion material 514b may include quantum dots approximately 4 nm in size. The green color conversion material 514c may include quantum dots approximately 2 nm in size. In other embodiments, the color conversion material 514 may include nanostructures, photoluminescent materials, or organic substances.

An encapsulation layer 522 is disposed over, and in some embodiments directly on, a top surface of the SI structures 510 and the sub-pixels 512. The encapsulation layer 522 prevents reactions between the color conversion material 514 and other materials in an ambient environment. The encapsulation layer 522 has a thickness from 10 nm or less and is one of a metal layer, a metal oxide layer, or a silicon containing layer. The encapsulation layer includes, but is not limited to, aluminum oxide, titanium oxide, silicon nitride, tantalum (Ta) hafnium (Hf), tantalum oxide, hafnium oxide, titanium (Ti), aluminum (Al), chromium (Cr), copper (Cu), tungsten (W), zirconium (Zr), or a combination thereof. The encapsulation layer 522 may be deposited using a physical vapor deposition (PVD) process, chemical vapor deposition (CVD), or atomic layer deposition (ALD). The PVD process may include pulsed laser deposition (PLD), thermal evaporation, or electron beam evaporation PVD (EBPVD).

In some embodiments, the pixel 500 includes micro-lenses 528 disposed on the encapsulation layer 522 and over each of the wells 513 of the sub-pixels 512. In some embodiments, a passivation layer 526 is disposed on the micro-lenses 528. In other embodiments, the micro-lenses 528 may be made of a resist material such as photoresist material that blocks UV light.

While the foregoing is direct to examples of the present disclosure, other and further examples of the disclosure may be devised without departing from the basic scope thereof, and the scope thereof is determined by the claims that follow.

What is claimed is:

1. A method for forming a light emitting diode (LED) device, comprising:
using laser irradiation to remove a carrier substrate from the LED device;
oxidizing a residual liquid metal layer formed by the laser irradiation by soaking the LED device in de-ionized water;
rinsing the de-ionized water off the LED device; and
drying the LED device using a drying process.

2. The method of claim 1, wherein the de-ionized water is heated to a temperature between 60 and 100° C.

3. The method of claim 1, wherein the residual liquid metal layer comprises gallium (Ga).

4. The method of claim 3, wherein oxidizing the residual liquid metal layer transforms the residual liquid metal layer into a transparent layer comprising gallium oxide hydroxide (GaOH), gallium hydroxide (GaH), or combinations thereof.

5. The method of claim 1, wherein rinsing the de-ionized water off the LED device comprises:
rinsing the LED device using a first soaking process for a first duration of time; and
rinsing the LED device using a second soaking process for a second duration of time.

6. The method of claim 5, wherein the first soaking process comprising soaking the LED device in acetone for the first duration of time, and the second soaking process comprises soaking the LED device in isopropyl alcohol (IPA) for the second duration of time.

7. The method of claim 1, wherein the drying process comprises a first drying process and a second drying process.

8. The method of claim 7, wherein the first drying process comprises air drying the LED device for a first duration of time, and the second drying process comprises heating or baking the LED device at a temperature for a second duration of time.

9. The method of claim 8, wherein the LED device is heated by placing the LED device in direct contact with a resistive heat source and the LED device is baked in an oven.

10. A method for forming a light emitting diode (LED) device, comprising:
using laser irradiation to remove a carrier substrate from the LED device, the carrier substrate having gallium nitride (GaN) LEDs formed on a carrier surface of the carrier substrate;
oxidizing a Ga residual layer formed by the laser irradiation by soaking the LED device in de-ionized water;
rinsing the de-ionized water off the LED device; and
drying the LED device using a drying process.

11. The method of claim 10, wherein the de-ionized water is heated to a temperature between 60 and 100° C.

12. The method of claim 10, wherein rinsing the de-ionized water off the LED device comprises:
rinsing the LED device using a first soaking process for a first duration of time; and
rinsing the LED device using a second soaking process for a second duration of time.

13. The method of claim 12, wherein the first soaking process comprising soaking the LED device in acetone for the first duration of time, and the second soaking process comprises soaking the LED device in isopropyl alcohol (IPA) for the second duration of time.

14. The method of claim 10, wherein the drying process comprises a first drying process and a second drying process.

15. The method of claim 14, wherein the first drying process comprises air drying the LED device for a first duration of time, and the second drying process comprises heating or baking the LED device at a temperature for a second duration of time.

16. The method of claim 15, wherein the LED device is heated by placing the LED device in direct contact with a resistive heat source and the LED device is baked in an oven.

17. The method of claim 9, wherein oxidizing Ga residual layer transforms the Ga residual layer into a transparent layer comprising gallium oxide hydroxide (GaOH), gallium hydroxide (GaH), or combinations thereof.

18. A device comprising:
a backplane having backplane electrodes; and
a plurality of light emitting diodes (LEDs) coupled to the backplane, the plurality of LEDs comprising:
a transparent layer formed on a first side of an epilayer; and
LED electrodes formed on a second side of the epilayer that are coupled to the backplane electrodes.

19. The device of claim 18, wherein the transparent layer is transparent to at least one of light having wavelengths in the visible light spectrum and light having wavelengths in the infrared (IR) wavelength spectrum.

20. The device of claim 18, wherein the transparent layer comprises gallium oxide hydroxide (GaOH), gallium hydroxide (GaH), or combinations thereof.
